(19) United States
(12) Patent Application Publication
(10) Pub. No.: US 2014/0202389 A1
(43) Pub. Date: Jul. 24, 2014

(54) APPARATUS FOR FABRICATING INGOT

(71) Applicants: Seon Heo, Seoul (KR); Dong Geun Shin, Seoul (KR)

(72) Inventors: Seon Heo, Seoul (KR); Dong Geun Shin, Seoul (KR)

(73) Assignee: LG INNOTEK CO., LTD., Seoul (KR)

(21) Appl. No.: 14/125,006

(22) PCT Filed: Jun. 8, 2012
(86) PCT No.: PCT/KR2012/004541

§ 371 Date: Feb. 20, 2014

(30) Foreign Application Priority Data
Jun. 8, 2011 (KR) 10-2011-0055296

(51) Int. Cl. C30B 23/00

(52) U.S. Cl. CPC C30B 23/005
USPC 118/726

(57) ABSTRACT

Disclosed is an apparatus for fabricating an ingot. The apparatus includes a crucible receiving a raw material, and comprising an upper portion and a lower portion opposite to each other, and seed holders disposed at the upper and lower portions, respectively.

### TECHNICAL FIELD

The disclosure relates to an apparatus for fabricating an ingot.

### BACKGROUND ART

In general, materials are very important factors to determine the property and the performance of final products in the electric, electronic and mechanical industrial fields.

SiC represents the superior thermal stability and superior oxidation-resistance property. In addition, the SiC has the superior thermal conductivity of about 4.6 W/Cm?, so the SiC can be used for fabricating a large-size substrate having a diameter of about 2 inches or above. In particular, the single crystal growth technology for the SiC is very stable actually, so the SiC has been extensively used in the industrial field as a material for a substrate.

In the case of SiC, a scheme of growing the single crystal for SiC has been suggested through a seeded growth sublimation scheme. In this case, after putting SiC powders serving as a raw material in a crucible, a SiC single crystal serving as a seed is provided on the raw material. Temperature gradient is formed between the raw material and the seed, so that the raw material in the crucible is dispersed to the seed, and re-crystallized to grow a single crystal.

When growing the single crystal, long time of about 70 hours or more is spent, so that the product yield of the single crystal may be lowered. In addition, if the rate of growing the single crystal is increased in order to increase the product yield of the single crystal, the quality of the single crystal may be lowered.

### DISCLOSURE OF INVENTION

### Technical Problem

The embodiment can grow a high-quality single crystal and improve the product yield of the single crystal.

According to the embodiment, there is provided an apparatus for fabricating an ingot. The apparatus includes a crucible to receive a raw material. The crucible has upper and lower portions opposite to each other, and seed holders are positioned on the upper and lower portions of the crucible.

### Solution to Problem

According to the embodiment, there is provided an apparatus for fabricating an ingot. The apparatus includes a crucible to receive a raw material. The crucible has upper and lower portions opposite to each other, and seed holders are positioned on the upper and lower portions of the crucible.

### Advantageous Effects of Invention

As described above, according to the apparatus for fabricating the ingot, the seed holders are provided at the upper and lower portions of the crucible, respectively. Therefore, single crystals can be grown in the upper and lower portions of the crucible. In other words, two single crystals can be grown through one process of growing a single crystal. Therefore, the fabricating cost and the fabricating time can be reduced. In addition, the high-quality single crystal can be grown while the product yield of the single crystal can be increased.

In addition, single crystals having different crystal structures can be grown in the upper and lower portions of the crucible. The single crystals may have different physical characteristics and different electrical characteristics according to the crystal structures, and the application fields of the single crystal can be varied according to the characteristics. Therefore, the single crystals having different crystal structures are grown, so that the variety and the efficiency of the process can be increased.

The raw materials used to grow the single crystal include polymer containing silicon and carbon. In more detail, the raw material may include polycarbosilane. The polycarbosilane is used as a raw material instead of SiC powder according to the related art, so that the fabricating time can be reduced, and the fabricating process can be simplified. This is because the synthetic process of fabricating the SiC powder according to the related art can be omitted. In other words, the polycarbosilane is used as the raw material, so that the SiC raw material can be simultaneously synthesized and grown.

In addition, after the SiC powders have been synthesized, when the SiC powders are filled in the crucible, the raw material can be prevented from being contaminated. Therefore, the impurities can be prevented from being introduced into the single crystal, and the high-quality single crystal can be grown.

Further, since the polycarbosilane has a fibrous structure, the problem related to the dust can be previously prevented when the powders are used.

Thereafter, the raw material can be exhausted consumed by using the polycarbosilane as the raw material. Accordingly, the quantity of single crystals created with respect to introduced raw material in the process can be quantified. In addition, after the single crystal has been produced, the raw material can be fully exhausted, thereby preventing an inconvenient work of recovering and reusing the raw material in the crucible.

The apparatus for fabricating the ingot according to the embodiment includes a filter part. The filter part allows a specific component to selectively pass through the filter part. In detail, the material sublimated from the raw material includes SiC₂, Si₂C, Si, and C impurities, and the filter part can adsorb C impurities. In other words, the filter part can prevent the C impurities come from the raw material from participating in the process of growing the single crystal. If the C impurities are moved into the single crystal, the single crystal may be defective. The filter part can prevent the single crystal from being defective.

### BRIEF DESCRIPTION OF DRAWINGS

FIG. 1 is a sectional view showing an apparatus for fabricating an ingot according to the embodiment; and

FIG. 2 is an enlarged sectional view showing a part A of FIG. 1.

### MODE FOR THE INVENTION

In the description of the embodiments, it will be understood that, when a layer (or film), a region, a pattern, or a structure is referred to as being “on”or “under” another layer (or film), another region, another pad, or another pattern, it can be “directly” or “indirectly” on the other layer (or film), region, pad, or pattern, or one or more intervening layers may also be present. Such a position of the layer has been described with reference to the drawings.

The thickness and size of each layer (film), region, pattern, or structure shown in the drawings may be exaggerated, omitted or schematically drawn for the purpose of convenience or clarity. In addition, the size of each layer (film), region, pattern, or structure does not utterly reflect an actual size.

Hereinafter, the embodiment of the present invention will be described in detail with reference to accompanying drawings.

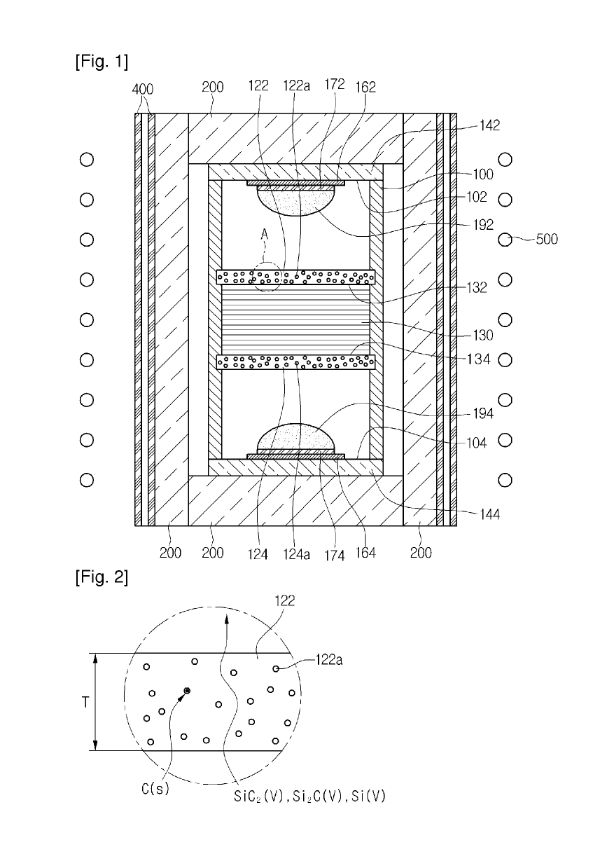

Hereinafter, an apparatus for fabricating an ingot will be described in detail with reference to FIGS. 1 and 2. FIG. 1 is a sectional view showing an apparatus for fabricating an ingot according to the embodiment, and FIG. 2 is an enlarged sectional view showing a part A of FIG. 1.

Referring to FIG. 1, the apparatus for fabricating the ingot includes a crucible 100, an upper cover 142, a lower cover 144, seed holders 162 and 164, filter parts 122 and 124, an adiabatic material 200, a quartz tube 400, and a heat induction part 500.

The crucible 100 receives raw materials 130 therein.

The crucible 100 has a cylindrical shape to receive the raw materials 130.

The crucible 100 may include a material having the melting point higher than the sublimation temperature of the SiC.

For example, the crucible 100 can be manufactured by using graphite.

In addition, the crucible 100 can be manufactured by coating a material having the melting point higher than the sublimation temperature of the SiC on the graphite. Preferably, a material, which is chemically inert with respect to silicon and hydrogen at the growth temperature for the SiC single crystals 192 and 194, is used as the material coated on the graphite. For instance, the material may include metal carbide or nitride carbide. In particular, a mixture including at least two of Ta, Hf, Nb, Zr, W and V and carbide including carbon can be coated on the graphite. Further, a mixture including at least two of Ta, Hf, Nb, Zr, W and V and nitride including nitrogen can be coated on the graphite.

The crucible 100 includes upper and lower portions 102 and 104 opposite to each other. The upper and lower portions 102 and 104 of the crucible 100 may be open.

Thereafter, the upper cover 142 may be positioned at the upper portion 102 of the crucible 100. In addition, the lower cover 144 may be positioned at the lower portion 104 of the crucible 100.

The upper and lower covers 142 and 144 are positioned at the upper and lower portions 102 and 104 of the crucible 100 to seal the crucible 100. The upper and lower covers 142 and 144 may include graphite.

The seed holders 162 and 164 include first and second seed holders 162 and 164. The first seed holder 162 is positioned on a lower end of the upper cover 142. In addition, the second holder 164 may be positioned on a lower end of the lower cover 144. The first and second seed holders 162 and 164 fix seeds 172 and 174, respectively. The seed holders 162 and 164 may include high-concentration graphite.

The seeds 172 and 174 are attached to the first and second seed holders 162 and 164, respectively. The seeds 172 and 174 are attached to the first and second seed holders 162 and 164 to prevent single crystals 192 and 194 from being grown to the upper and lower covers 142 and 144. However, the embodiment is not limited thereto, and the seeds 172 and 174 may be directly attached to the upper and the lower covers 142 and 144, respectively.

According to the apparatus for fabricating the ingot of the embodiment, the seed holders 162 and 164 are positioned at the upper and lower portions 102 and 104 of the crucible 100, respectively, so that the single crystals 192 and 194 can be grown at the lower portion 104 as well as the upper portion 102. In other words, two single crystals 192 and 194 can be grown through one single crystal growing process. Accordingly, the fabricating cost and the fabricating time can be saved. In addition, the product yield of the single crystal can be increased.

According to the related art, although the rate of growing the single crystal is increased in order to increase the production yield of the single crystal, the quality of the single crystal grown through the above method may be degraded. However, according to the present embodiment, high-quality single crystals can be grown while the product yield of the single crystals can be increased.

The raw materials 130 may include silicon and carbon. In detail, the raw materials 130 may include a compound containing silicon, carbon, oxygen, and hydrogen. In more detail, the raw material 130 may include polymer containing silicon and carbon. For example, the raw material 130 may include polycarbosilane.

The polycarbosilane is a kind of polysilane. The polycarbosilane is polymer having a backbone chain of Si and C. The polycarbosilane is pre-ceramic raw material used as raw material for a high performance fiber such as SiC fiber having a micro-diameter which is used for an ultra high temperature. Since the polycarbosilane, which is polymer, can be easily processed in various forms, the polycarbonsilane is variously applicable in a fibrous form, a film-like form, a porous form, a coating form, and the like. According to the apparatus for fabricating the ingot according to the present embodiment, polycarbosilane used as the raw material 130 has a fibrous structure.

Polycarbosilane having the fibrous structure may be prepared through one of a melt-spinning scheme, a melt-blown scheme, and an electro-spinning scheme that are generally known in the art. However, the embodiment is not limited, and the fibrous polycarbosilane may be prepared through various schemes.

The fibrous polycarbosilane may be piled at the central portion of the crucible 100.

If the polycarbosilane is maintained at the temperature of about 1200? to 1500° C. for several hours, the polycarbosilane is subject to organic-inorganic transformation through thermal-decomposition. Thereafter, the polycarbosilane is converted into SiC.

If a temperature is raised to the growth temperature of a single crystal of the SiC, impurities such as SiC₂, Si₂C, Si and C are come from the SiC.

The SiC₂, Si₂C and Si are sublimated and moved to the seeds 192 and 194 so that single crystals 192 and 194 can be grown.

The fabricating time can be reduced, and the fabricating process can be simplified by using the polycarbosilane as a raw material instead of existing SiC powder. This is because a synthesizing process to prepare the existing SiC power can be omitted. In other words, SiC raw material is simultaneously synthesized and grown by using the polycarbosilane as a raw material.

In addition, after synthesizing the SiC powder, when the SiC powder is filled in the crucible 100, the raw material can be prevented from being contaminated. Therefore, impurities can be prevented from being introduced into the single crystal, so that a high-quality single crystal can be grown.

Further, since polycarbosilane has a fibrous structure, dust problems to be caused when the powders are used can be previously prevented.

Thereafter, the raw material 130 can be fully consumed by using the fibrous polycarbosilane as the raw material 130. Accordingly, the quantity of single crystals created with respect to introduced raw material in the process can be quantified. In addition, after the single crystal has been produced, the raw material can be fully consumed, thereby preventing an inconvenient work of recovering and reusing the raw material in the crucible.

According to the present embodiment, since the single crystal 194 is formed even at the lower portion 104 of the crucible 100 as well as the upper portion 102 of the crucible 100, an influence must not be exerted on the quality of the single crystal 194 grown from the lower portion 104. If the raw material 130 includes existing SiC powders, the SiC powders may be dropped to the seed 174 positioned at the lower portion 104 of the crucible 100 before sublimation occurs. This may be a cause to create poly crystals. According to the present embodiment, the creation of the poly crystals can be prevented by using the fibrous raw material 130.

Next, the filter parts 122 and 124 may be positioned inside the crucible 100. In more detail, the raw material 130 includes a top surface 132 and a bottom surface 134 opposite to each other. The filter parts 122 and 124 may be positioned on at least one of the top and bottom surfaces 132 and 134.

The filter parts 122 and 124 include the first and second filter parts 122 and 124. The first filter part 122 may be positioned on the top surface 132 of the raw material 130. The second filter part 124 may be positioned on the bottom surface 134 of the raw material 130.

The filter parts 122 and 124 may allow specific components to selectively pass through the filter part 122 and 124. In detail, the filter parts 122 and 124 may adsorb carbon impurities. In other words, the carbon impurities come from the raw material 130 can be prevented from participating in the process of growing the single crystals 192 and 194. If the carbon impurities are moved to the crystals 192 and 194, the crystals 192 and 194 may be defective.

In addition, the second filter part 124 positioned on the bottom surface 134 of the raw material 130 can prevent residues after the sublimation of the raw material 130 from being dropped to the single crystal 194 positioned at the lower portion 104 of the crucible 100.

The filter parts 122 and 124 may have the thickness T in the range of 1 mm to 10 cm. The thickness T of the filter parts 122 and 124 may be varied according to the size of the crucible 100, and the scale of the crucible 100. If the filter parts 122 and 124 have a thickness T of 1 mm or less, the thickness T is excessively thin, so that the filter parts 122 and 124 may not adsorb the carbon impurities. If the filter parts 122 and 124 have the thickness T of 10 cm or more, the thickness T is very thick, so that the speed to transmit materials other than carbon impurities may be reduced. In other words, the speed to transmit SiC₂, Si₂C, and Si used to grow the single crystals 192 and 194 may be reduced. Accordingly, the speed to grow the single crystals 192 and 194 may be reduced.

The filter parts 122 and 124 may have a porous structure. In other words, the filter parts 122 and 124 may have a plurality of pores 122a and 124a. Referring to FIG. 2, the pores 122a and 124a can adsorb C impurities having a very small size and contaminants. In addition, the filter parts 122 and 124 may allow SiC₂, Si₂C and Si to pass through the filter parts 122 and 124 and move SiC₂, Si₂C and Si to the seeds 172 and 174.

The filter parts 122 and 124 may include a membrane. In detail, the filter parts 122 and 124 may include a carbon-based membrane.

The carbon-based membrane may be prepared by compression-molding and calcining graphite powder. The carbon-based membrane represents superior durability, a superior penetration property, and superior filterability. Therefore, when the filter parts 122 and 124 include the carbon-based membrane, the high-quality single crystals 192 and 194 can be prepared.

However, the embodiment is not limited thereto, so that the filter parts 122 and 124 may include various materials representing superior durability, a superior penetration property, and superior filterability.

The adiabatic material 200 surrounds the crucible 100. The adiabatic material 200 keeps the temperature of the crucible 100 to the level of the crystal growth temperature. Since the crystal growth temperature of the SiC is high, graphite felt may be used as the adiabatic material 200. In detail, the adiabatic material 200 may include a cylindrical graphite felt having a predetermined thickness prepared by compressing graphite fiber. In addition, the adiabatic material 200 may be prepared as a plurality of layers to surround the crucible 100.

The quartz tube 400 is positioned at an outer peripheral surface of the crucible 100. The quartz tube 400 is fitted around the outer peripheral surface of the crucible 100. The quartz tube 400 may block heat transferred into a single crystal growth apparatus from the heat induction part 500. The quartz tube 400 is a hollow tube and cooling water may circulate through an inner space of the quartz tube 400.

The heat induction part 500 is positioned outside the crucible 100. For instance, the heat induction part 500 is an RF induction coil. As RF current is applied to the RF induction coil, the crucible 100 and the raw material 130 can be heated. That is, the raw materials 130 contained in the crucible 100 can be heated to the desired temperature.

The central portion of the crucible 100 having the raw material 130 positioned therein is heated at a temperature different from the temperature of heating the upper and lower portions 102 and 104 of the crucible, which is called the temperature gradient. Due to the temperature gradient, the raw materials 130 may be sublimated so that the sublimated SiC gas moves to the surface of the seeds 172 and 174 having the relatively low temperature. Thus, the SiC gas is re-crystallized, so the single crystals 192 and 194 are grown.

According to the apparatus for fabricating the ingot of the present embodiment, the temperature of the upper portion 102 may be different from the temperature of the lower portion 104 by adjusting the position of the heat induction part 500. Therefore, the single crystals 192 and 194 may be grown in different crystal structures at the upper and lower portions 102 and 104. The single crystals 192 and 194 may have different physical properties and different electrical characteristics according to the crystal structures, and the applications of the single crystals 192 and 194 may be varied according to the physical properties and the electrical characteristics. Therefore, the variety and the efficiency of the processes can be enhanced by growing the single crystals 192 and 194 having crystal structures different from each other.

For example, a 4-H (hexagonal) single crystal 192 may be grown at the upper portion 102 and a 6-H (hexagonal) single crystal 194 may be grown at the lower portion 104. However, since the embodiment is not limited thereto, various single crystals can be fabricated through one process.

Any reference in this specification to “one embodiment,” “on embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. An apparatus for fabricating an ingot, the apparatus comprising:
a crucible receiving a raw material, and comprising an upper portion and a lower portion opposite to each other; and
seed holders disposed at the upper and lower portions, respectively.

2. The apparatus of claim 1, wherein the raw material comprises top and bottom surfaces opposite to each other, and a filter part is provided on at least one of the top and bottom surfaces so that a specific component selectively passes through the filter part.

3. The apparatus of claim 2, wherein the filter part comprises:
a first filter part disposed on the top surface of the raw material; and
a second filter part disposed on the bottom surface of the raw material.

4. The apparatus of claim 1, wherein ingots are grown in the upper and lower portions, respectively.

5. The apparatus of claim 1, wherein the raw material is disposed at a central portion of the crucible.

6. The apparatus of claim 1, wherein the raw material includes a compound containing silicon and carbon.

7. The apparatus of claim 1, wherein the raw material includes a compound containing silicon, carbon, oxygen, and hydrogen.

8. The apparatus of claim 6, wherein the raw material includes polymer containing silicon and carbon.

9. The apparatus of claim 8, wherein the raw material includes polycarbosilane.

10. The apparatus of claim 1, wherein the raw material has a fibrous structure.

11. The apparatus of claim 2, wherein the filter part transmits silicon carbide gas.

12. The apparatus of claim 2, wherein the filter part includes a membrane.

13. The apparatus of claim 12, wherein the filter part has a thickness in a range of 1 mm to 10 cm.

14. The apparatus of claim 2, wherein the filter part is porous.

15. The apparatus of claim 12, wherein the membrane is a carbon-based membrane.
